(19) United States
(12) Patent Application Publication
(10) Pub. No.: US 2024/0105861 A1
(43) Pub. Date: Mar. 28, 2024

(54) OPTICAL SYSTEM PACKAGING

(71) Applicant: ams International AG, JONA (CH)

(72) Inventor: Tiao ZHOU, Frisco, TX (US)

(73) Assignee: ams International AG, JONA (CH)

(21) Appl. No.: 18/257,116

(22) PCT Filed: Dec. 3, 2021
(86) PCT No.: PCT/EP2021/084137

§ 371 Date: Jun. 13, 2023

(30) Foreign Application Priority Data
Dec. 15, 2020 (GB) 2019752.1

(51) Int. Cl. H01L 31/0203; H01L 25/16; H01L 31/12

(52) U.S. Cl. CPC H01L 31/0203; H01L 25/165; H01L 25/167; H01L 31/125

(57) ABSTRACT

An optical system includes a circuit board, an optical emitter device mounted on the circuit board, and a cap mounted on the circuit board. The cap and the circuit board together define a chamber therebetween, the chamber enclosing the optical emitter device. The cap includes one or more opaque regions and one or more transparent regions, wherein the one or more opaque regions of the cap are configured to prevent light emitted from the optical emitter device from travelling out of the chamber in one or more undesirable directions, wherein the one or more transparent regions of the cap are configured to allow light emitted from the optical emitter device to travel out of the chamber in one or more desirable directions. The cap is formed by rendering one or more selected regions of a transparent substrate to be opaque, or by forming one or more opaque features on a transparent substrate, so that the one or more opaque regions of the cap include the one or more opaque regions of the substrate or the one or more opaque features formed on the substrate, and so that the one or more transparent regions of the cap include one or more transparent regions of the substrate. The optical system may include one or more optical emitter devices and/or one or more optical detector devices.

### CROSS-REFERENCE TO RELATED APPLICATIONS

The present application is the national stage entry of International Patent Application No. PCT/EP2021/084137, filed on Dec. 3, 2021, and published as WO 2022/128529 A1 on Jun. 23, 2022, which claims the benefit of priority of Great Britain Patent Application No. 2019752.1, filed on Dec. 15, 2020, the disclosures of all of which are incorporated by reference herein in their entireties.

### FIELD

The present disclosure relates to optical system packaging and, in particular though not exclusively, to an optical system including one or more optical emitter devices and/or one or more optical detector devices, and to a cap for use in such an optical system.

### BACKGROUND

It is known to manufacture an optical sensor system which includes an optical emitter device for emitting light towards a target object and an optical detector device for detecting light returning from the target object, wherein the optical emitter and optical detector devices are mounted on a PCB, and wherein each of the optical emitter and optical detector devices is encapsulated in a clear mold material to protect the optical emitter and optical detector devices from an environment external to the optical emitter and optical detector devices.

For example, referring to FIG. 1 there is shown a prior art optical sensor system generally designated 2 which includes an optical emitter device in the form of a surface-emitting optical emitter device 4 and an optical detector device 6 mounted on a PCB 8. Both the optical emitter device 4 and the optical detector device 6 are encapsulated by a clear mold material 9 such as a clear epoxy material. The optical sensor 2 includes an opaque cap 10 which defines a first aperture 12 and a second aperture 14. The opaque cap 10 is mounted on the PCB 8 over the optical emitter and detector devices 4, 6 so that the first aperture 12 is aligned with the optical emitter device 4 to allow light emitted by the optical emitter device 4 to be transmitted through the clear epoxy material 9 and out through the first aperture 12 towards the target object and so that the second aperture 14 is aligned with the optical detector device 6 to allow light returning from the target object in through the second aperture 14, through the clear epoxy material 9 and onto the optical detector device 6. The opaque cap 10 also prevents stray light from being transmitted in one or more undesirable directions directly from the optical emitter device 4 to the optical detector device 6 without first interacting with the target object. As such, the opaque cap 10 may reduce cross-talk.

The method of manufacturing the optical sensor system 2 described above may have several drawbacks. Firstly, the clear mold material 9 may have a higher coefficient of thermal expansion (CTE) than the optical emitter device 4 or the optical detector device 6. Additionally or alternatively, the clear mold material 9 may have a low glass transition temperature (Tg). These mechanical properties of the clear mold material 9 may be undesirable because they may result in high stress levels between the clear mold material 9 and the optical emitter device 4 or between the clear mold material 9 and the optical detector device 6 in the presence of temperature variations e.g. during environmental tests such as temperature cycling. Such high stress levels may degrade the operation of the optical emitter device 4 and/or the operation of the optical detector device 6. Such high stress levels may even cause the optical emitter device 4 and/or the optical detector device 6 to fail, for example because fragile wire bonds between the optical emitter device 4 and the PCB 8 or between the optical detector device 6 and the PCB 8 can break upon expansion. Furthermore, the clear mold material 9 may absorb moisture easily and this may negatively affect the optical transmission through the clear mold material 9 and/or the performance of the optical emitter device 4 and/or the optical detector device 6. Artefacts such as voids, bubbles or the like may also be present, or may form, in the clear mold material 9 thereby obstructing, distorting or scattering the light emitted by the optical emitter device 4 and/or the light received by the optical detector device 6. Consequently, the use of the clear mold material 9 may lead to a degradation in the performance and/or in the reliability of the optical sensor system 2.

It is also known to manufacture an optical sensor system which includes an optical emitter device for emitting light towards a target object and an optical detector device for detecting light returning from the target object, wherein the optical emitter and optical detector devices are mounted, for example flip-chip bonded, on the underside of an electrical connection member. The electrical connection member is then mounted on a PCB so that the optical emitter device and the optical detector device are both suspended below the electrical connection member in a gap defined between the underside of the electrical connection member and an upper surface of the PCB. In such an optical sensor system, the electrical connection member provides one or more electrically conductive connections between the optical emitter device and the PCB and one or more electrically conductive connections between the optical detector device and the PCB. However, this approach cannot be used for sensor packages where wire bonds are used as interconnects between optical emitter/detector devices and a PCB. Moreover, such an optical sensor system may be susceptible to cross-talk as a result of stray light being transmitted in one or more undesirable directions directly from the optical emitter device to the optical detector device without first interacting with the target object.

### SUMMARY

According to an aspect of the present disclosure there is provided an optical system comprising:
a circuit board;
an optical emitter device mounted on the circuit board; and
a cap mounted on the circuit board,
wherein the cap and the circuit board together define a chamber therebetween, the chamber enclosing the optical emitter device,
wherein the cap comprises one or more opaque regions and one or more transparent regions,
wherein the one or more opaque regions of the cap are configured to prevent light emitted from the optical emitter device from travelling out of the chamber in one or more undesirable directions,
wherein the one or more transparent regions of the cap are configured to allow light emitted from the optical emitter device to travel out of the chamber in one or more desirable directions, and
wherein the cap is formed by rendering one or more selected regions of a transparent substrate to be opaque, or by forming one or more opaque features on a transparent substrate, so that the one or more opaque regions of the cap comprise the one or more opaque regions of the substrate or the one or more opaque features formed on the substrate, and so that the one or more transparent regions of the cap comprise one or more transparent regions of the substrate.

Such an optical system may provide mechanical protection for the optical emitter device in the chamber without any requirement to encapsulate the optical emitter device in a clear mold material. Avoiding any requirement to encapsulate the optical emitter device in a clear mold material may improve the performance and/or the reliability of the optical system. Avoiding any requirement to encapsulate the optical emitter device in a clear mold material may also allow light to be emitted from the optical system without obstructing, distorting or scattering the light emitted from the optical emitter device.

The optical emitter device may comprise a light emitting surface area.

The optical emitter device may comprise one or more electrical contacts adjacent to the light emitting surface area of the optical emitter device.

The optical system may comprise one or more electrical interconnections between the optical emitter device and the circuit board. For example, the optical system may comprise one or more wire bond interconnections, wherein each wire bond interconnection extends from a corresponding electrical contact of the optical emitter device to the circuit board.

The light emitting surface area of the optical emitter device and the one or more transparent regions of the cap may be separated by a gap. The presence of such a gap may prevent any physical contact between the light emitting surface area of the optical emitter device and the one or more transparent regions of the cap. The presence of such a gap may allow for differences in the CTE of the optical emitter device and the one or more transparent regions of the cap and may prevent any damage resulting from differential expansion of the optical emitter device and the one or more transparent regions of the cap as a result of any changes in temperature. The presence of such a gap may allow one or more electrically conductive connections to be made between one or more of the electrical contacts of the optical emitter device and the circuit board. In particular, the presence of such a gap may allow one or more wire bond interconnections to be made between one or more of the electrical contacts of the optical emitter device and the circuit board.

The cap may define a recess in a surface thereof. The one or more transparent regions of the cap may be located at a closed end of the recess. An open end of the recess may be disposed towards the circuit board. The open end of the recess may be located over the optical emitter device so that the recess and the circuit board together define the chamber.

According to an aspect of the present disclosure there is provided an optical system, comprising:
a circuit board;
a plurality of optical emitter devices mounted on the circuit board; and
a cap mounted on the circuit board,
wherein the cap and the circuit board together define a plurality of chambers therebetween, each chamber enclosing a corresponding one of the optical emitter devices,
wherein the cap comprises a plurality of transparent regions,
wherein the one or more opaque regions of the cap are configured to prevent light emitted from each optical emitter device from travelling out of the corresponding chamber in one or more undesirable directions,
wherein each transparent region of the cap is configured to allow light emitted from a corresponding optical emitter device to travel out of a corresponding chamber in one or more desirable directions, and
wherein the cap is formed by rendering one or more selected regions of a transparent substrate to be opaque, or by forming one or more opaque features on a transparent substrate, so that the one or more opaque regions of the cap comprise the one or more opaque regions of the substrate or the one or more opaque features formed on the substrate, and so that each of the transparent regions of the cap comprises a corresponding transparent region of the substrate.

Each optical emitter device may comprise a light emitting surface area.

Each optical emitter device may comprise one or more electrical contacts adjacent to the light emitting surface area of the optical emitter device.

The optical system may comprise one or more electrical interconnections between each optical emitter device and the circuit board.

The optical system may comprise one or more wire bond interconnections, wherein each wire bond interconnection extends from a corresponding electrical contact of a corresponding optical emitter device to the circuit board.

The light emitting surface area of each optical emitter device and the one or more corresponding transparent regions of the cap may be separated by a gap.

The cap may define a plurality of recesses in a surface thereof. One or more of the transparent regions of the cap may be located at a closed end of each recess. An open end of each recess may be disposed towards the circuit board. The open end of each recess may be located over a corresponding optical emitter device so that each recess and the circuit board together define the corresponding chamber enclosing the corresponding optical emitter device.

According to an aspect of the present disclosure there is provided an optical system comprising:
a circuit board;
an optical detector device mounted on the circuit board; and
a cap mounted on the circuit board,
wherein the cap and the circuit board together define a chamber therebetween, the chamber enclosing the optical detector device,
wherein the cap comprises one or more opaque regions and one or more transparent regions,
wherein the one or more opaque regions of the cap are configured to prevent light from travelling into the chamber from one or more undesirable directions,
wherein the one or more transparent regions of the cap are configured to allow light to travel into the chamber and to impinge on the optical detector device in the chamber from one or more desirable directions, and
wherein the cap is formed by rendering one or more selected regions of a transparent substrate to be opaque, or by forming one or more opaque features on a transparent substrate, so that the one or more opaque regions of the cap comprise the one or more opaque regions of the substrate or the one or more opaque features formed on the substrate, and so that the one or more transparent regions of the cap comprise one or more transparent regions of the substrate.

Such an optical system may provide mechanical protection for the optical detector device in the chamber without any requirement to encapsulate the optical detector device in a clear mold material. Avoiding any requirement to encapsulate the optical detector device in a clear mold material may improve the performance and/or the reliability of the optical system. Avoiding any requirement to encapsulate the optical detector device in a clear mold material may also allow light to be received by the optical detector device without the light being obstructed, distorted or scattered before the light impinges on the optical detector device.

The optical detector device may comprise a light receiving surface area.

The optical detector device may comprise one or more electrical contacts adjacent to the light receiving surface area of the optical detector device.

The optical system may comprise one or more electrical interconnections between the optical detector device and the circuit board.

The optical system may comprise one or more wire bond interconnections, wherein each wire bond interconnection extends from a corresponding electrical contact of the optical detector device to the circuit board.

The light receiving surface area of the optical detector device and the one or more corresponding transparent regions of the cap may be separated by a gap.

The cap may define a recess in a surface thereof. The one or more transparent regions of the cap may be located at a closed end of the recess. An open end of the recess may be disposed towards the circuit board. The open end of the recess may be located over the optical detector device so that the recess and the circuit board together define the chamber.

According to an aspect of the present disclosure there is provided an optical system, comprising:
a circuit board;
a plurality of optical detector devices mounted on the circuit board; and
a cap mounted on the circuit board,
wherein the cap and the circuit board together define a plurality of chambers therebetween, each chamber enclosing a corresponding one of the optical detector devices,
wherein the cap comprises a plurality of transparent regions,
wherein the one or more opaque regions of the cap are configured to prevent light from travelling into each chamber and from impinging on the corresponding optical detector device in each chamber from one or more undesirable directions,
wherein each transparent region of the cap is configured to allow light to travel into a corresponding chamber and to impinge on the corresponding optical detector device in the corresponding chamber from one or more desirable directions, and
wherein the cap is formed by rendering one or more selected regions of a transparent substrate to be opaque, or by forming one or more opaque features on a transparent substrate, so that the one or more opaque regions of the cap comprise the one or more opaque regions of the substrate or the one or more opaque features formed on the substrate, and so that each of the transparent regions of the cap comprises a corresponding transparent region of the substrate.

Each optical detector device may comprise a light receiving surface area.

Each optical detector device may comprise one or more electrical contacts adjacent to the light receiving surface area of the optical detector device.

The optical system may comprise one or more electrical interconnections between each optical detector device and the circuit board.

The optical system may comprise one or more wire bond interconnections, wherein each wire bond interconnection extends from a corresponding electrical contact of a corresponding optical detector device to the circuit board.

The light receiving surface area of each optical detector device and the one or more corresponding transparent regions of the cap may be separated by a gap.

The cap may define one or more recesses in a surface thereof. One or more of the transparent regions of the cap may be located at a closed end of each recess. An open end of each recess may be disposed towards the circuit board. The open end of each recess may be located over a corresponding optical detector device so that each recess and the circuit board together define the corresponding chamber enclosing the corresponding optical detector device.

According to an aspect of the present disclosure there is provided an optical system comprising:
a circuit board;
an optical emitter device mounted on the circuit board and an optical detector device mounted on the circuit board; and
a cap mounted on the circuit board,
wherein the cap and the circuit board together define first and second chambers therebetween, the first chamber enclosing the optical emitter device and the second chamber enclosing the optical detector device,
wherein the cap comprises one or more opaque regions, and first and second transparent regions,
wherein the one or more opaque regions of the cap are configured to prevent light emitted from the optical emitter device from travelling out of the first chamber in one or more undesirable directions and to prevent light from travelling into the second chamber from one or more undesirable directions,
wherein the first transparent region of the cap is configured to allow light emitted from the optical emitter device to travel out of the first chamber in one or more desirable directions, and the second transparent region of the cap is configured to allow light to travel into the second chamber and to impinge on the optical detector device in the second chamber from one or more desirable directions, and
wherein the cap is formed by rendering one or more selected regions of a transparent substrate to be opaque, or by forming one or more opaque features on a transparent substrate, so that the one or more opaque regions of the cap comprise the one or more opaque regions of the substrate or the one or more opaque features formed on the substrate, and so that the first transparent region of the cap comprises a first transparent region of the substrate and the second transparent region of the cap. comprises a second transparent region of the substrate.

Such an optical system may provide mechanical protection for the optical emitter device in the first sealed chamber and the optical detector device in the second sealed chamber without any requirement to encapsulate the optical emitter device or the optical detector device in a clear mold material. Avoiding any requirement to encapsulate the optical emitter device or the optical detector device in a clear mold material may improve the performance and/or the reliability of the optical system. Avoiding any requirement to encapsulate the optical emitter device in a clear mold material may also allow light to be emitted from the optical system without obstructing, distorting or scattering the light emitted from the optical emitter device. Similarly, avoiding any requirement to encapsulate the optical detector device in a clear mold material may also allow light to be received by the optical detector device without the light being obstructed, distorted or scattered before the light impinges on the optical detector device.

Such an optical system may prevent stray light from being transmitted in one or more undesirable directions directly from the optical emitter device to the optical detector device without first interacting with a target object. Consequently, such an optical system may reduce cross-talk between the optical emitter device and the optical detector device.

There may be no electrically conductive connections between the cap and the circuit board.

The cap may comprise an electrically insulating material.

The cap may be at least partially electrically conductive.

The cap may comprise an electrically conductive layer formed or deposited on a surface of the cap such as an inner or outer surface of the cap. Such an electrically conductive layer may shield the optical emitter device and/or the optical detector device from electromagnetic interference such as radio frequency electromagnetic interference.

The cap may be electrically passive.

The cap may be unitary and/or monolithic.

The substrate may comprise, or be formed from, a photosensitive material.

The photosensitive material may be electrically insulating.

The photosensitive material may be configurable from a transparent state to an opaque state.

The photosensitive material may comprise a photosensitive glass material which may be configurable from a transparent glass state to an opaque ceramic state.

The photosensitive glass material may be configurable from the transparent glass state to the opaque ceramic state upon exposure to UV light and heating.

An etchability of the photosensitive material with respect to an etchant substance may change upon exposure of the photosensitive material to UV light and heating.

An etch rate of the photosensitive material with respect to an etchant substance may be configurable between a lower etch rate and a higher etch rate upon exposure of the photosensitive material to UV light and heating.

The etchant substance may comprise an etchant fluid such as an etchant gas, an etchant liquid, or an etchant solution.

The etchant substance may comprise HF.

The photosensitive material may comprise at least one of:
APEX;
Photocor;
Foturan.

The one or more opaque features may be formed on the transparent substrate by a molding process, for example by injection molding a material such as LCP or by transfer molding a material such as an opaque epoxy.

The circuit board may comprise an insulating substrate and one or more electrical conductors.

The circuit board may comprise a PCB.

The cap may be attached to the circuit board using an adhesive, a glue or an epoxy such as a liquid epoxy or a pre-applied B-stage epoxy.

The chamber may be sealed.

The chamber may contain a fluid.

The chamber may contain a gas.

The chamber may contain air.

The chamber may contain an inert gas.

The chamber may contain a gas at a pressure which is less than a pressure of an environment external to the optical system.

The chamber may contain a vacuum.

The chamber may contain a liquid.

According to an aspect of the present disclosure there is provided a method of manufacturing an optical system, the method comprising:
mounting an optical emitter device on a circuit board; and
mounting a cap on the circuit board,
wherein the cap and the circuit board together define a chamber therebetween, the chamber enclosing the optical emitter device,
wherein the cap comprises one or more opaque regions and one or more transparent regions,
wherein the one or more opaque regions of the cap are configured to prevent light emitted from the optical emitter device from travelling out of the chamber in one or more undesirable directions,
wherein the one or more transparent regions of the cap are configured to allow light emitted from the optical emitter device to travel out of the chamber in one or more desirable directions, and
wherein the cap is formed by rendering one or more selected regions of a transparent substrate to be opaque, or by forming one or more opaque features on a transparent substrate, so that the one or more opaque regions of the cap comprise the one or more opaque regions of the substrate or the one or more opaque features formed on the substrate, and so that the one or more transparent regions of the cap comprise one or more transparent regions of the substrate.

The cap may comprise a recess and the method may comprise disposing an open end of the recess towards the circuit board and locating an open end of the recess of the cap over the optical emitter device so that the recess and the circuit board together define the chamber.

According to an aspect of the present disclosure there is provided a method of manufacturing an optical system, the method comprising:
mounting a plurality of optical emitter devices on a circuit board; and
mounting a cap on the circuit board,
wherein the cap and the circuit board together define a plurality of chambers therebetween, each chamber enclosing a corresponding optical emitter device,
wherein the cap comprises a plurality of transparent regions,
wherein the one or more opaque regions of the cap are configured to prevent light emitted from each optical emitter device from travelling out of the corresponding chamber in one or more undesirable directions,
wherein each transparent region of the cap is configured to allow light emitted from a corresponding optical emitter device to travel out of a corresponding chamber in one or more desirable directions, and
wherein the cap is formed by rendering one or more selected regions of a transparent substrate to be opaque, or by forming one or more opaque features on a transparent substrate, so that the one or more opaque regions of the cap comprise the one or more opaque regions of the substrate or the one or more opaque features formed on the substrate, and so that each of the transparent regions of the cap comprises a corresponding transparent region of the substrate.

The cap may comprise a plurality of recesses and the method may comprise disposing an open end of each recess of the cap towards the circuit board and locating an open end of each recess of the cap over a corresponding optical emitter device so that each recess and the circuit board together define the corresponding chamber enclosing the corresponding optical emitter device.

According to an aspect of the present disclosure there is provided a method of manufacturing an optical system, the method comprising:
mounting an optical detector device on a circuit board; and
mounting a cap on the circuit board,
wherein the cap and the circuit board together define a chamber therebetween, the chamber enclosing the optical detector device,
wherein the cap comprises one or more opaque regions and one or more transparent regions,
wherein the one or more opaque regions of the cap are configured to prevent light from travelling into the chamber from one or more undesirable directions,
wherein the one or more transparent regions of the cap are configured to allow light to travel into the chamber and to impinge on the optical detector device in the chamber from one or more desirable directions, and
wherein the cap is formed by rendering one or more selected regions of a transparent substrate to be opaque, or by forming one or more opaque features on a transparent substrate, so that the one or more opaque regions of the cap comprise the one or more opaque regions of the substrate or the one or more opaque features formed on the substrate, and so that the one or more transparent regions of the cap comprise one or more transparent regions of the substrate.

The cap may comprise a recess and the method may comprise disposing an open end of the recess towards the circuit board and locating an open end of the recess of the cap over the optical detector device so that the recess and the circuit board together define the chamber.

According to an aspect of the present disclosure there is provided a method of manufacturing an optical system, the method comprising:
mounting a plurality of optical detector devices on a circuit board; and
mounting a cap on the circuit board,
wherein the cap and the circuit board together define a plurality of chambers therebetween, each chamber enclosing a corresponding one of the optical detector devices,
wherein the cap comprises a plurality of transparent regions,
wherein the one or more opaque regions of the cap are configured to prevent light from travelling into each chamber and from impinging on the corresponding optical detector device in each chamber from one or more undesirable directions,
wherein each transparent region of the cap is configured to allow light to travel into a corresponding chamber and to impinge on the corresponding optical detector device in the corresponding chamber from one or more desirable directions, and
wherein the cap is formed by rendering one or more selected regions of a transparent substrate to be opaque, or by forming one or more opaque features on a transparent substrate, so that the one or more opaque regions of the cap comprise the one or more opaque regions of the substrate or the one or more opaque features formed on the substrate, and so that each of the transparent regions of the cap comprises a corresponding transparent region of the substrate.

The cap may comprise a plurality of recesses and the method may comprise disposing an open end of each recess of the cap towards the circuit board and locating an open end of each recess of the cap over a corresponding optical detector device so that each recess and the circuit board together define the corresponding chamber enclosing the corresponding optical detector device.

According to an aspect of the present disclosure there is provided a method of manufacturing an optical sensor system, the method comprising:
mounting an optical emitter device on a circuit board;
mounting an optical detector device on the circuit board; and
mounting a cap on the circuit board,
wherein the cap and the circuit board together define first and second chambers therebetween, the first chamber enclosing the optical emitter device and the second chamber enclosing the optical detector device,
wherein the cap comprises one or more opaque regions, and first and second transparent regions,
wherein the one or more opaque regions of the cap are configured to prevent light emitted from the optical emitter device from travelling out of the first chamber in one or more undesirable directions and to prevent light from travelling into the second chamber from one or more undesirable directions,
wherein the first transparent region of the cap is configured to allow light emitted from the optical emitter device to travel out of the first chamber in one or more desirable directions, and the second transparent region of the cap is configured to allow light to travel into the second chamber and to impinge on the optical detector device in the second chamber from one or more desirable directions, and
wherein the cap is formed by rendering one or more selected regions of a transparent substrate to be opaque, or by forming one or more opaque features on a transparent substrate, so that the one or more opaque regions of the cap comprise the one or more opaque regions of the substrate or the one or more opaque features formed on the substrate, and so that the first transparent region of the cap comprises a first transparent region of the substrate and the second transparent region of the cap comprises a second transparent region of the substrate.

There may be no electrically conductive connections between the cap and the circuit board.

The cap may comprise one or more electrically insulating materials.

The cap may be electrically passive.

The cap may comprise an electrically conductive layer formed or deposited on a surface of the cap such as an inner or outer surface of the cap. Such an electrically conductive layer may shield the optical emitter device from electromagnetic interference such as radio frequency electromagnetic interference.

The method may comprise forming the cap.

Forming the cap may comprise rendering the one or more selected regions of the transparent substrate to be opaque.

Forming the cap may comprise forming one or more recesses in the transparent substrate, each recess being configured to accommodate a corresponding optical emitter device or a corresponding optical detector device.

Forming the cap may comprise forming the one or more opaque features on the transparent substrate.

Forming the one or more opaque features on the transparent substrate may comprise molding a material on the transparent substrate, for example by injection molding a material such as LCP or transfer molding a material such as an opaque epoxy.

The one or more opaque features formed on the transparent substrate may define one or more recesses, each recess being configured to accommodate a corresponding optical emitter device or a corresponding optical detector device.

Each optical emitter device may be configured to emit visible and/or infra-red light.

Each optical emitter device may comprise a surface emitting optical emitter device such as a surface emitting LED device or a surface emitting laser device such as a VCSEL device.

Each optical emitter device may comprise a plurality of optical emitters.

Each optical emitter device may comprise a 1D or 2D array of optical emitters.

Each optical emitter device may comprise a uniform array of optical emitters.

Each optical detector device may be configured to detect visible and/or infra-red light.

Each optical detector device may comprise a plurality of optical detectors.

Each optical detector device may comprise a plurality of light sensitive areas or pixels.

Each optical detector device may comprise a 1D or 2D array of optical detectors.

Each optical detector device may comprise a uniform array of optical detectors.

Each optical detector device may comprise an image sensor.

According to an aspect of the present disclosure there is provided a cap for an optical system, the cap comprising one or more opaque regions and one or more transparent regions, wherein the cap is formed by rendering one or more selected regions of a transparent substrate to be opaque, or by forming one or more opaque features on a transparent substrate, so that the one or more opaque regions of the cap comprise the one or more opaque regions of the substrate or the one or more opaque features formed on the substrate, and so that the one or more transparent regions of the cap comprises one or more transparent regions of the substrate.

The cap may define a recess in a surface thereof and the one or more transparent regions of the cap may be located at a closed end of the recess.

According to an aspect of the present disclosure there is provided a method of manufacturing a cap for an optical system, the method comprising rendering one or more selected regions of a transparent substrate to be opaque.

The method may comprise forming a recess in the transparent substrate.

According to an aspect of the present disclosure there is provided a method of manufacturing a cap for an optical system, the method comprising forming one or more opaque features on a transparent substrate.

Forming the one or more opaque features on the transparent substrate may comprise molding a material on the transparent substrate, for example by injection molding a material such as LCP or transfer molding a material such as an opaque epoxy.

The one or more opaque features that are formed on the transparent substrate may define a recess.

According to an aspect of the present disclosure there is provided a method of manufacturing a plurality of caps for a plurality of optical systems, the method comprising:
forming an integrated array of two or more caps using any of the methods for forming the cap described above; and
separating, dividing, singulating, dicing or sawing the integrated array of caps so as to provide a plurality of caps.

Such a method may allow a plurality of caps to be manufactured using wafer-level processing techniques.

It should be understood that any one or more of the features of any one of the foregoing aspects of the present disclosure may be combined with any one or more of the features of any of the other foregoing aspects of the present disclosure.

### BRIEF DESCRIPTION OF THE DRAWINGS

An optical system will now be described by way of non-limiting example only with reference to the accompanying drawings of which:

FIG. 1 is a schematic of a prior art optical sensor system including an optical emitter device and an optical detector device;

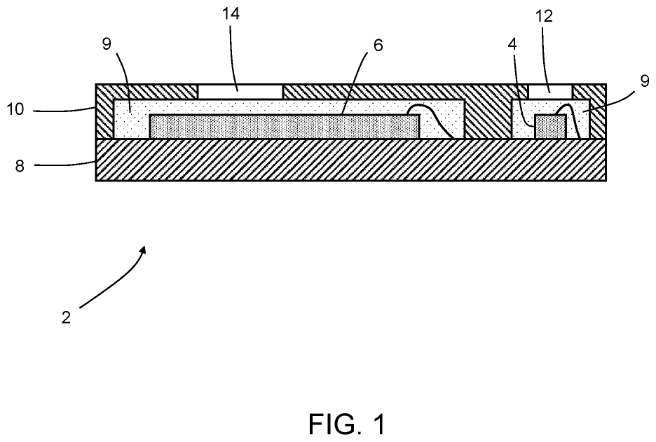

FIG. 2 is a schematic of an optical sensor system including an optical emitter device and an optical detector device;

FIGS. 3A-3F schematically illustrate the steps of a method of manufacturing a cap of the optical sensor system of FIG. 2;

FIG. 4 is a schematic of an alternative optical sensor system including an optical emitter device and an optical detector device; and

FIGS. 5A-5E schematically illustrate the steps of a method of manufacturing a plurality of optical sensor systems like the optical sensor system of FIG. 4.

### DETAILED DESCRIPTION OF THE DRAWINGS

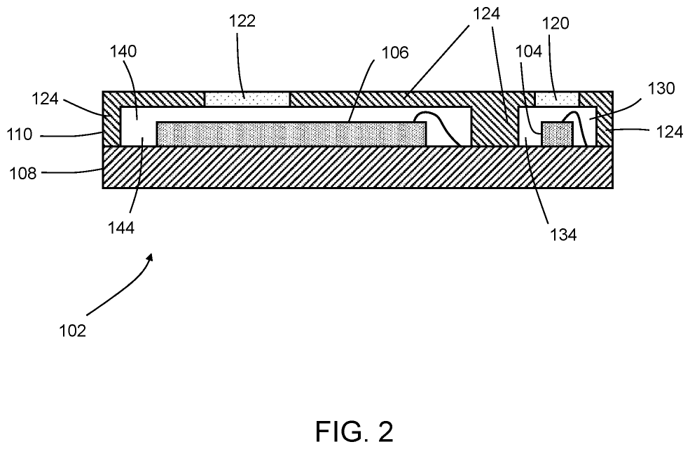

Referring initially to FIG. 2, there is shown an optical sensor system generally designated 102 which includes an optical emitter device in the form of a surface-emitting optical emitter device 104 and an optical detector device 106 mounted on a circuit board in the form of a PCB 108. The optical sensor 102 includes a monolithic or unitary cap 110 which defines a first transparent window 120, a second transparent window 122 and one or more opaque regions 124.

The cap 110 is mounted on the PCB 108 over the optical emitter device 104 so that the cap 110 and the PCB 108 together define a first chamber 130 therebetween, the first chamber 130 enclosing the optical emitter device 104. The one or more opaque regions 124 of the cap block light emitted from the optical emitter device 104 from travelling out of the first chamber 130 in one or more undesirable directions, whilst the first transparent window 120 allows light emitted from the optical emitter device 104 to travel out of the first chamber 130 in one or more desirable directions towards a target object (not shown).

Specifically, the cap 110 defines a first recess 134 in a lower surface thereof, wherein the first transparent window 120 is located at a closed end of the first recess 134, and wherein the open end of the first recess 134 is disposed towards the PCB 108. The open end of the first recess 134 is located over the optical emitter device 104 so that the first recess 134 and the PCB 108 together define the first chamber 130.

Similarly, the cap 110 is mounted on the PCB 108 over the optical detector device 106 so that the cap 110 and the PCB 108 together define a second chamber 140 therebetween, the second chamber 140 enclosing the optical detector device 106. The one or more opaque regions 124 of the cap 110 block light from travelling into the second chamber 140 from one or more undesirable directions, whilst the second transparent window 122 allows light to travel into the second chamber 140 from the target object in one or more desirable directions and to impinge on the optical detector device 106.

Specifically, the cap 110 defines a second recess 144 in the lower surface thereof, wherein the second transparent window 122 is located at a closed end of the second recess 144, and wherein the open end of the second recess 144 is disposed towards the PCB 108. The open end of the second recess 144 is located over the optical detector device 106 so that the second recess 144 and the PCB 108 together define the second chamber 140.

The cap 110 prevents stray light from being transmitted in one or more undesirable directions directly from the optical emitter device 104 to the optical detector device 106 without first interacting with the target object. As such, the cap 110 reduces cross-talk from the optical emitter device 104 to the optical detector device 106.

Moreover, the cap 110 provides mechanical protection for the optical emitter device 104 in the first sealed chamber 130 without any requirement to encapsulate the optical emitter device 104 in a clear mold material. Avoiding any requirement to encapsulate the optical emitter device 104 in a clear mold material improves the performance and/or the reliability of the optical emitter device 104. Avoiding any requirement to encapsulate the optical emitter device 104 in a clear mold material also allows light to be emitted from the optical emitter device 104 without obstructing, distorting or scattering the light emitted from the optical system 102.

Similarly, the cap 110 provides mechanical protection for the optical detector device 106 in the second sealed chamber 140 without any requirement to encapsulate the optical detector device 106 in a clear mold material. Avoiding any requirement to encapsulate the optical detector device 106 in a clear mold material may improve the performance and/or the reliability of the optical detector device 106. Avoiding any requirement to encapsulate the optical detector device 106 in a clear mold material may also allow light to be detected by the optical detector device 106 without obstructing, distorting or scattering the light which impinges on the optical system 102.

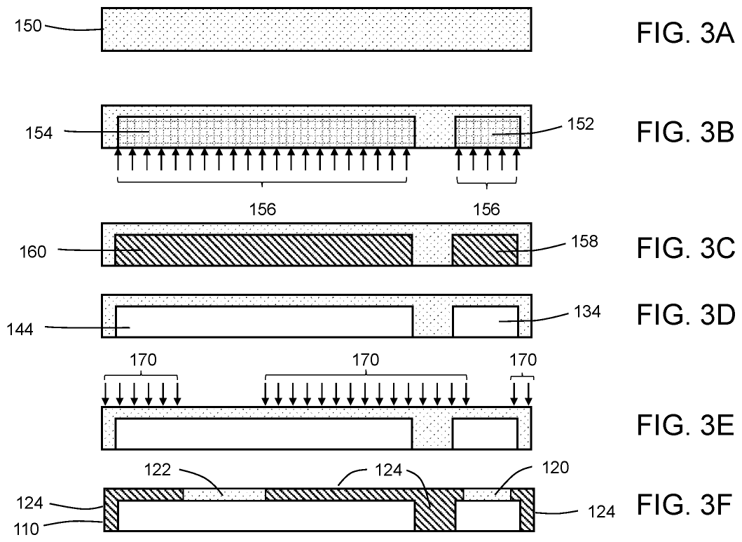

A method for manufacturing the monolithic or unitary cap 110 will now be described with reference to FIGS. 3A to 3F. As shown in FIG. 3A, the method begins with the provision of a substrate 150 formed from a photosensitive glass material such as APEX. As shown in FIG. 3B, selected regions 152 and 154 of a lower surface of the substrate 150 are exposed to UV light 156. As shown in FIG. 3C, the substrate 150 is then heated, for example baked, so as to configure the exposed regions 152 and 154 of the substrate 150 from a transparent glass state to an opaque ceramic state to form opaque ceramic regions 158 and 160 with increased etchability to an etchant such as HF. The substrate 150 is then exposed to HF causing substrate material to be etched away in the opaque ceramic regions 158 and 160 resulting in the formation of the first and second downwardly-directed recesses 134 and 144 respectively as shown in FIG. 3D. As shown in FIG. 3E, further selected regions of the substrate 150 are then exposed to UV light 170. The substrate 150 is then heated, for example baked, so as to configure the further exposed regions of the substrate 150 from a transparent glass state to an opaque ceramic state to thereby define the opaque regions 124 of the cap 110 whilst also effectively defining the first and second transparent windows 120, 122 at the closed ends of the first and second recesses 134, 144 to thereby produce the cap 110 as shown in FIG. 3F.

From the foregoing description of the method for manufacturing the monolithic or unitary cap 110 with reference to FIGS. 3A to 3F, one of ordinary skill in the art will understand that an integrated array of monolithic or unitary caps may be manufactured at a wafer level and then cut, for example sawed, along selected lines so as to provide a plurality of individual monolithic or unitary caps, each individual monolithic or unitary cap like the monolithic or unitary cap 110 shown in FIG. 3F.

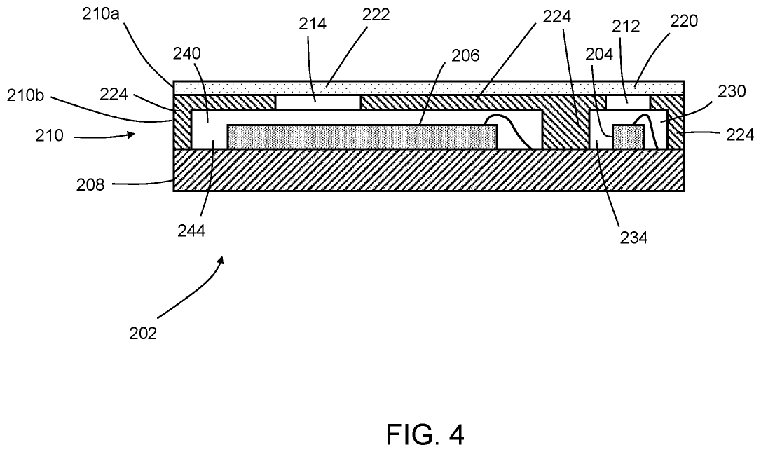

Referring now to FIG. 4, there is shown an alternative optical sensor system generally designated 202 which includes an optical emitter device in the form of a surface-emitting optical emitter device 204 and an optical detector device 206 mounted on a circuit board in the form of a PCB 208. The optical sensor 202 includes a cap 210 which defines a first transparent window 220, a second transparent window 222 and one or more opaque regions 224. The cap 210 is formed by molding an opaque material such a LCP or an opaque epoxy material onto a transparent glass sheet member 210a to form an opaque light barrier 210b defining a first aperture 212, a second aperture 214, and the one or more opaque regions 224 of the cap 210. A portion of the glass sheet member 210a located above the first aperture 212 defines the first transparent window 220 of the cap 210. Similarly, a portion of the glass sheet member 210a located above the second aperture 212 defines the second transparent window 222 of the cap 210.

The cap 210 is mounted on the PCB 208 over the optical emitter device 204 so that the cap 210 and the PCB 208 together define a first chamber 230 therebetween, the first chamber 230 enclosing the optical emitter device 204, and the one or more opaque regions 224 of the cap 220 block light emitted from the optical emitter device 204 from travelling out of the first chamber 230 in one or more undesirable directions, whilst the first transparent window 220 allows light emitted from the optical emitter device 204 to travel out of the first chamber 230 in one or more desirable directions towards a target object (not shown).

Specifically, the cap 210 defines a first recess 234 in a lower surface thereof, wherein the first transparent window 220 is located at a closed end of the first recess 234, and wherein the open end of the first recess 234 is disposed towards the PCB 208. The open end of the first recess 234 is located over the optical emitter device 204 so that the first recess 234 and the PCB 208 together define the first chamber 230.

Similarly, the cap 210 is mounted on the PCB 208 over the optical detector device 206 so that the cap 210 and the PCB 208 together define a second sealed chamber 240 therebetween, the second chamber 240 enclosing the optical detector device 206, and the one or more opaque regions 224 of the cap 210 block light from travelling into the second chamber 240 from one or more undesirable directions, whilst the second transparent window 222 allows light to travel into the second chamber 240 from the target object in one or more desirable directions and to impinge on the optical detector device 206.

Specifically, the cap 210 defines a second recess 244 in the lower surface thereof, wherein the second transparent window 222 is located at a closed end of the second recess 244, and wherein the open end of the second recess 244 is disposed towards the PCB 108. The open end of the second recess 244 is located over the optical detector device 206 so that the second recess 244 and the PCB 208 together define the second chamber 240.

The cap 210 prevents stray light from being transmitted in one or more undesirable directions directly from the optical emitter device 204 to the optical detector device 206 without first interacting with the target object. As such, the cap 210 reduces cross-talk from the optical emitter device 204 to the optical detector device 206.

Moreover, the cap 210 provides mechanical protection for the optical emitter device 204 in the first chamber 230 without any requirement to encapsulate the optical emitter device 204 in a clear mold material. Avoiding any requirement to encapsulate the optical emitter device 204 in a clear mold material improves the performance and/or the reliability of the optical emitter device 204. Avoiding any requirement to encapsulate the optical emitter device 204 in a clear mold material also allows light to be emitted from the optical emitter device 204 without obstructing, distorting or scattering the light emitted from the optical system 202.

Similarly, the cap 210 provides mechanical protection for the optical detector device 206 in the second chamber 240 without any requirement to encapsulate the optical detector device 206 in a clear mold material. Avoiding any requirement to encapsulate the optical detector device 206 in a clear mold material may improve the performance and/or the reliability of the optical detector device 206. Avoiding any requirement to encapsulate the optical detector device 206 in a clear mold material may also allow light to be detected by the optical detector device 106 without obstructing, distorting or scattering the light which impinges on the optical system 202.

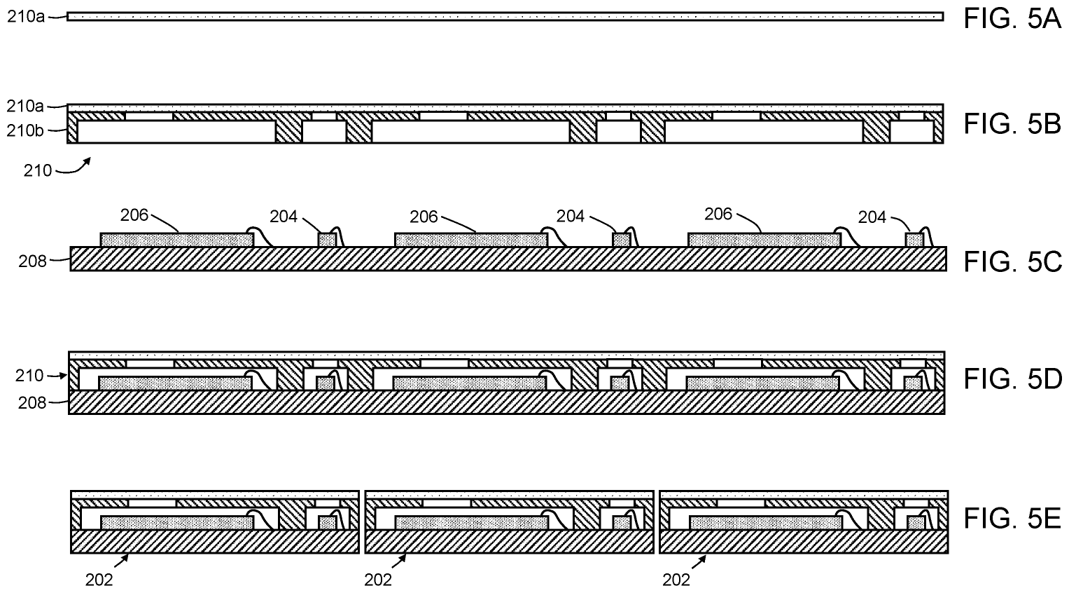

As described below with reference to FIGS. 5A-5E, an integrated array of optical systems 202 may be manufactured at a wafer level and the integrated optical systems 202 cut, for example sawed, along selected lines so as to provide a plurality of individual optical systems 202, each individual optical systems like the optical system 202 described above with reference to FIG. 4. Specifically, a method of manufacturing the optical system 202 may begin with the step of providing the transparent glass sheet member 210a shown in FIG. 5A. An opaque LCP material is molded onto the transparent glass sheet member 210a, for example using injection molding or transfer molding, so as to produce an integrated array of caps 210 as shown in FIG. 5B. A plurality of optical emitter devices 204 and a plurality of optical detector devices 206 are mounted on the PCB 208 and a plurality of wire bond connections are formed between each optical emitter device 204 and the PCB 208 and between each optical detector device 206 and the PCB 208 to form the populated PCB array shown in FIG. 5C. The integrated array of caps 210 is then bonded to the populated PCB array to obtain an integrated array of optical systems as shown in FIG. 5D. The integrated array of optical systems is then cut, for example sawed, along selected lines so as to provide a plurality of individual optical systems 202 as shown in FIG. 5E.

Alternatively, the integrated array of caps 210 may be manufactured at a wafer level as described above with reference to FIGS. 5A and 5B and the integrated array of caps 210 cut, for example sawed, along selected lines so as to provide a plurality of individual caps, each individual cap like the cap 210 described above with reference to FIG. 4. Each individual cap 210 may then be aligned relative to the corresponding optical emitter device 204 mounted on the PCB 208 and the corresponding optical detector device 206 mounted on the PCB 208.

Although preferred embodiments of the disclosure have been described in terms as set forth above, it should be understood that these embodiments are illustrative only and that the claims are not limited to those embodiments. Those skilled in the art will understand that various modifications may be made to the described embodiments without departing from the scope of the appended claims. For example, in each of the optical systems 102, 202 described with reference to FIGS. 2 and 4, the optical system 102, 202 includes an optical emitter device 104, 204 and an optical detector device 106, 206.

In a variant of either of the optical systems 102, 202, the variant optical system may include a PCB, an optical emitter device mounted on the PCB and a cap mounted on the PCB, wherein the cap and the circuit board together define a chamber therebetween, the chamber enclosing the optical emitter device, and the cap having one or more opaque regions and one or more transparent regions, wherein the one or more opaque regions of the cap are configured to prevent light emitted from the optical emitter device from travelling out of the chamber in one or more undesirable directions, and wherein the one or more transparent regions of the cap are configured to allow light emitted from the optical emitter device to travel out of the chamber in one or more desirable directions i.e. the variant optical system may exclude an optical detector device, the variant optical system may exclude a further chamber enclosing the optical detector device, and the variant optical system may exclude a transparent window for transmitting light travelling into the further chamber from one or more desirable directions and allowing the transmitted light to impinge on the optical detector device.

Conversely, in a further variant of either of the optical systems 102, 202, the variant optical system may include a PCB, an optical detector device mounted on the PCB and a cap mounted on the PCB, wherein the cap and the circuit board together define a sealed chamber therebetween, the chamber enclosing the optical detector device, and the cap having one or more opaque regions and one or more transparent regions, wherein the one or more opaque regions of the cap are configured to prevent light from travelling into the chamber from one or more undesirable directions, and wherein the one or more transparent regions of the cap are configured to allow light to travel into the chamber and to impinge on the optical detector device in the chamber from one or more desirable directions i.e. the variant optical system may exclude an optical emitter device, the variant optical system may exclude a further chamber enclosing the optical emitter device, and the variant optical system may exclude a transparent window for transmitting light emitted from the optical emitter device out of the further chamber in one or more desirable directions.

In other variants, the optical emitter device may be configured to emit visible and/or infra-red light. The optical emitter device may comprise a surface emitting optical emitter device such as a surface emitting LED device or a surface emitting laser device such as a VCSEL device. The optical emitter device may comprise a plurality of optical emitters. The optical emitter device may comprise a 1D or 2D array of optical emitters. The optical emitter device may comprise a uniform array of optical emitters.

The optical detector device may be configured to detect visible and/or infra-red light. The optical detector device may comprise a plurality of light sensitive areas or pixels. The optical detector device may comprise a 1D or 2D array of optical detectors. The optical detector device may comprise a uniform array of optical detectors. The optical detector device may comprise an image sensor.

The first chamber 130, 230 and/or the second chamber 140, 240 may be sealed from an environment external to the optical system 102, 202. The first chamber 130, 230 and/or the second chamber 140, 240 may contain a fluid such as a gas or a liquid. For example, the first chamber 130, 230 and/or the second chamber 140, 240 may contain air or an inert gas. The first chamber 130, 230 and/or the second chamber 140, 240 may contain a gas at a pressure which is less than a pressure of the external environment, for example, the first chamber 130, 230 and/or the second chamber 140, 240 may contain a vacuum.

Each feature disclosed or illustrated in the present specification may be incorporated in any embodiment, either alone, or in any appropriate combination with any other feature disclosed or illustrated herein. In particular, one of ordinary skill in the art will understand that one or more of the features of the embodiments of the present disclosure described above with reference to the drawings may produce effects or provide advantages when used in isolation from one or more of the other features of the embodiments of the present disclosure and that different combinations of the features are possible other than the specific combinations of the features of the embodiments of the present disclosure described above.

The skilled person will understand that in the preceding description and appended claims, positional terms such as ‘above’, ‘along’, ‘side’, etc. are made with reference to conceptual illustrations, such as those shown in the appended drawings. These terms are used for ease of reference but are not intended to be of limiting nature. These terms are therefore to be understood as referring to an object when in an orientation as shown in the accompanying drawings.

Use of the term “comprising” when used in relation to a feature of an embodiment of the present disclosure does not exclude other features or steps. Use of the term “a” or “an” when used in relation to a feature of an embodiment of the present disclosure does not exclude the possibility that the embodiment may include a plurality of such features.

The use of reference signs in the claims should not be construed as limiting the scope of the claims.

1. An optical system comprising:
a circuit board;
an optical emitter device mounted on the circuit board; and
a cap mounted on the circuit board,
wherein the cap and the circuit board together define a chamber therebetween, the chamber enclosing the optical emitter device,
wherein the cap comprises one or more opaque regions and one or more transparent regions,
wherein the one or more opaque regions of the cap are configured to prevent light emitted from the optical emitter device from travelling out of the chamber in one or more undesirable directions,
wherein the one or more transparent regions of the cap are configured to allow light emitted from the optical emitter device to travel out of the chamber in one or more desirable directions, and
wherein the cap is formed by rendering one or more selected regions of a transparent substrate to be opaque, or by forming one or more opaque features on a transparent substrate, so that the one or more opaque regions of the cap comprise the one or more opaque regions of the substrate or the one or more opaque features formed on the substrate, and so that the one or more transparent regions of the cap comprise one or more transparent regions of the substrate.

2. An optical system, comprising:
a circuit board;
a plurality of optical emitter devices mounted on the circuit board; and
a cap mounted on the circuit board,
wherein the cap and the circuit board together define a plurality of chambers therebetween, each chamber enclosing a corresponding one of the optical emitter devices,
wherein the cap comprises a plurality of transparent regions,
wherein the one or more opaque regions of the cap are configured to prevent light emitted from each optical emitter device from travelling out of the corresponding chamber in one or more undesirable directions,
wherein each transparent region of the cap is configured to allow light emitted from a corresponding optical emitter device to travel out of a corresponding chamber in one or more desirable directions, and
wherein the cap is formed by rendering one or more selected regions of a transparent substrate to be opaque, or by forming one or more opaque features on a transparent substrate, so that the one or more opaque regions of the cap comprise the one or more opaque regions of the substrate or the one or more opaque features formed on the substrate, and so that each of the transparent regions of the cap comprises a corresponding transparent region of the substrate.

3. The optical system as claimed in claim 1, wherein at least one of:
each optical emitter device comprises a light emitting surface area;
each optical emitter device comprises one or more electrical contacts adjacent to the light emitting surface area of the optical emitter device;
the optical system comprises one or more electrical interconnections between each optical emitter device and the circuit board;
the optical system comprises one or more wire bond interconnections, wherein each wire bond interconnection extends from a corresponding electrical contact of a corresponding optical emitter device to the circuit board;
the light emitting surface area of each optical emitter device and the one or more corresponding transparent regions of the cap are separated by a gap.

4. The optical system as claimed in any claim 1, wherein the cap defines one or more recesses in a surface thereof, one or more of the transparent regions of the cap are located at a closed end of each recess, an open end of each recess is disposed towards the circuit board, and the open end of each recess is located over a corresponding optical emitter device so that each recess and the circuit board together define the corresponding chamber enclosing the corresponding optical emitter device.

5. An optical system comprising:
a circuit board;
an optical detector device mounted on the circuit board; and
a cap mounted on the circuit board,
wherein the cap and the circuit board together define a chamber therebetween, the chamber enclosing the optical detector device,
wherein the cap comprises one or more opaque regions and one or more transparent regions,
wherein the one or more opaque regions of the cap are configured to prevent light from travelling into the chamber from one or more undesirable directions,
wherein the one or more transparent regions of the cap are configured to allow light to travel into the chamber and to impinge on the optical detector device in the chamber from one or more desirable directions, and
wherein the cap is formed by rendering one or more selected regions of a transparent substrate to be opaque, or by forming one or more opaque features on a transparent substrate, so that the one or more opaque regions of the cap comprise the one or more opaque regions of the substrate or the one or more opaque features formed on the substrate, and so that the one or more transparent regions of the cap comprise one or more transparent regions of the substrate.

6. An optical system, comprising:
a circuit board;
a plurality of optical detector devices mounted on the circuit board; and
a cap mounted on the circuit board,
wherein the cap and the circuit board together define a plurality of chambers therebetween, each chamber enclosing a corresponding one of the optical detector devices,
wherein the cap comprises a plurality of transparent regions,
wherein the one or more opaque regions of the cap are configured to prevent light from travelling into each chamber and from impinging on the corresponding optical detector device in each chamber from one or more undesirable directions,
wherein each transparent region of the cap is configured to allow light to travel into a corresponding chamber and to impinge on the corresponding optical detector device in the corresponding chamber from one or more desirable directions, and
wherein the cap is formed by rendering one or more selected regions of a transparent substrate to be opaque, or by forming one or more opaque features on a transparent substrate, so that the one or more opaque regions of the cap comprise the one or more opaque regions of the substrate or the one or more opaque features formed on the substrate, and so that each of the transparent regions of the cap comprises a corresponding transparent region of the substrate.

7. The optical system as claimed in claim 5, wherein at least one of:
each optical detector device comprises a light receiving surface area;
each optical detector device comprises one or more electrical contacts adjacent to the light receiving surface area of the optical detector device;
the optical system comprises one or more electrical interconnections between each optical detector device and the circuit board;
the optical system comprises one or more wire bond interconnections, wherein each wire bond interconnection extends from a corresponding electrical contact of a corresponding optical detector device to the circuit board;
the light receiving surface area of each optical detector device and the one or more corresponding transparent regions of the cap are separated by a gap.

8. The optical system as claimed in claim 4, wherein the cap defines one or more recesses in a surface thereof, one or more of the transparent regions of the cap are located at a closed end of each recess, an open end of each recess is disposed towards the circuit board, and the open end of each recess is located over a corresponding optical detector device so that each recess and the circuit board together define the corresponding chamber enclosing the corresponding optical detector device.

9. An optical system comprising:
a circuit board;
an optical emitter device mounted on the circuit board and an optical detector device mounted on the circuit board; and
a cap mounted on the circuit board,
wherein the cap and the circuit board together define first and second chambers therebetween, the first chamber enclosing the optical emitter device and the second chamber enclosing the optical detector device,
wherein the cap comprises one or more opaque regions, and first and second transparent regions,
wherein the one or more opaque regions of the cap are configured to prevent light emitted from the optical emitter device from travelling out of the first chamber in one or more undesirable directions and to prevent light from travelling into the second chamber from one or more undesirable directions,
wherein the first transparent region of the cap is configured to allow light emitted from the optical emitter device to travel out of the first chamber in one or more desirable directions, and the second transparent region of the cap is configured to allow light to travel into the second chamber and to impinge on the optical detector device in the second chamber from one or more desirable directions, and
wherein the cap is formed by rendering one or more selected regions of a transparent substrate to be opaque, or by forming one or more opaque features on a transparent substrate, so that the one or more opaque regions of the cap comprise the one or more opaque regions of the substrate or the one or more opaque features formed on the substrate, and so that the first transparent region of the cap comprises a first transparent region of the substrate and the second transparent region of the cap comprises a second transparent region of the substrate.

10. The optical system as claimed in claim 1, wherein at least one of:
there are no electrically conductive connections between the cap and the circuit board;
the cap comprises an electrically insulating material;
the cap is at least partially electrically conductive;
the cap comprises an electrically conductive layer formed or deposited on a surface of the cap such as an inner or outer surface of the cap;
the cap is electrically passive.

11. The optical system as claimed in claim 1, wherein the cap is unitary and/or monolithic.

12. The optical system as claimed in claim 1, wherein at least one of:
the substrate comprises, or is formed from, a photosensitive material;
the photosensitive material is configurable from a transparent state to an opaque state;
the photosensitive material comprises a photosensitive glass material which is configurable from a transparent glass state to an opaque ceramic state;
the photosensitive glass material is configurable from the transparent glass state to the opaque ceramic state upon exposure to UV light and heating;
an etchability of the photosensitive material with respect to an etchant substance changes upon exposure of the photosensitive material to UV light and heating;
an etch rate of the photosensitive material with respect to an etchant substance is configurable between a lower etch rate and a higher etch rate upon exposure of the photosensitive material to UV light and heating;
the etchant substance comprises an etchant fluid such as an etchant gas, an etchant liquid, or an etchant solution;
the etchant substance comprises HF.

13. The optical system as claimed in claim 1, wherein the one or more opaque features are formed on the transparent substrate by a molding process, for example by injection molding a material such as LCP or by transfer molding a material such as an opaque epoxy.

14. A method of manufacturing an optical system, the method comprising:
mounting an optical emitter device on a circuit board; and
mounting a cap on the circuit board,
wherein the cap and the circuit board together define a chamber therebetween, the chamber enclosing the optical emitter device,
wherein the cap comprises one or more opaque regions and one or more transparent regions,
wherein the one or more opaque regions of the cap are configured to prevent light emitted from the optical emitter device from travelling out of the chamber in one or more undesirable directions,
wherein the one or more transparent regions of the cap are configured to allow light emitted from the optical emitter device to travel out of the chamber in one or more desirable directions, and
wherein the cap is formed by rendering one or more selected regions of a transparent substrate to be opaque, or by forming one or more opaque features on a transparent substrate, so that the one or more opaque regions of the cap comprise the one or more opaque regions of the substrate or the one or more opaque features formed on the substrate, and so that the one or more transparent regions of the cap comprise one or more transparent regions of the substrate.

15. A method of manufacturing an optical system, the method comprising:
mounting a plurality of optical emitter devices on a circuit board; and
mounting a cap on the circuit board,
wherein the cap and the circuit board together define a plurality of chambers therebetween, each chamber enclosing a corresponding optical emitter device,
wherein the cap comprises a plurality of transparent regions,
wherein the one or more opaque regions of the cap are configured to prevent light emitted from each optical emitter device from travelling out of the corresponding chamber in one or more undesirable directions,
wherein each transparent region of the cap is configured to allow light emitted from a corresponding optical emitter device to travel out of a corresponding chamber in one or more desirable directions, and
wherein the cap is formed by rendering one or more selected regions of a transparent substrate to be opaque, or by forming one or more opaque features on a transparent substrate, so that the one or more opaque regions of the cap comprise the one or more opaque regions of the substrate or the one or more opaque features formed on the substrate, and so that each of the transparent regions of the cap comprises a corresponding transparent region of the substrate.

16. A method of manufacturing an optical system, the method comprising:
mounting an optical detector device on a circuit board; and
mounting a cap on the circuit board,
wherein the cap and the circuit board together define a chamber therebetween, the chamber enclosing the optical detector device,
wherein the cap comprises one or more opaque regions and one or more transparent regions,
wherein the one or more opaque regions of the cap are configured to prevent light from travelling into the chamber from one or more undesirable directions,
wherein the one or more transparent regions of the cap are configured to allow light to travel into the chamber and to impinge on the optical detector device in the chamber from one or more desirable directions, and
wherein the cap is formed by rendering one or more selected regions of a transparent substrate to be opaque, or by forming one or more opaque features on a transparent substrate, so that the one or more opaque regions of the cap comprise the one or more opaque regions of the substrate or the one or more opaque features formed on the substrate, and so that the one or more transparent regions of the cap comprise one or more transparent regions of the substrate.

17. A method of manufacturing an optical system, the method comprising:
mounting a plurality of optical detector devices on a circuit board; and
mounting a cap on the circuit board,
wherein the cap and the circuit board together define a plurality of chambers therebetween, each chamber enclosing a corresponding one of the optical detector devices,
wherein the cap comprises a plurality of transparent regions,
wherein the one or more opaque regions of the cap are configured to prevent light from travelling into each chamber and from impinging on the corresponding optical detector device in each chamber from one or more undesirable directions,
wherein each transparent region of the cap is configured to allow light to travel into a corresponding chamber and to impinge on the corresponding optical detector device in the corresponding chamber from one or more desirable directions, and
wherein the cap is formed by rendering one or more selected regions of a transparent substrate to be opaque, or by forming one or more opaque features on a transparent substrate, so that the one or more opaque regions of the cap comprise the one or more opaque regions of the substrate or the one or more opaque features formed on the substrate, and so that each of the transparent regions of the cap comprises a corresponding transparent region of the substrate.

18. A method of manufacturing an optical system comprising:
mounting an optical emitter device on a circuit board;
mounting an optical detector device on the circuit board; and
mounting a cap on the circuit board,
wherein the cap and the circuit board together define first and second chambers therebetween, the first chamber enclosing the optical emitter device and the second chamber enclosing the optical detector device,
wherein the cap comprises one or more opaque regions, and first and second transparent regions,
wherein the one or more opaque regions of the cap are configured to prevent light emitted from the optical emitter device from travelling out of the first chamber in one or more undesirable directions and to prevent light from travelling into the second chamber from one or more undesirable directions,
wherein the first transparent region of the cap is configured to allow light emitted from the optical emitter device to travel out of the first chamber in one or more desirable directions, and the second transparent region of the cap is configured to allow light to travel into the second chamber and to impinge on the optical detector device in the second chamber from one or more desirable directions, and
wherein the cap is formed by rendering one or more selected regions of a transparent substrate to be opaque, or by forming one or more opaque features on a transparent substrate, so that the one or more opaque regions of the cap comprise the one or more opaque regions of the substrate or the one or more opaque features formed on the substrate, and so that the first transparent region of the cap comprises a first transparent region of the substrate and the second transparent region of the cap comprises a second transparent region of the substrate.

19. The method as claimed in claim 14, comprising forming the cap.

20. The method as claimed in claim 19, wherein forming the cap comprises rendering the one or more selected regions of the transparent substrate to be opaque.

21. The method as claimed in claim 20, wherein forming the cap comprises forming one or more recesses in the transparent substrate, each recess being configured to accommodate a corresponding optical emitter device or a corresponding optical detector device.

22. The method as claimed in claim 19, wherein forming the cap comprises forming the one or more opaque features on the transparent substrate.

23. The method as claimed in claim 22, wherein forming the one or more opaque features on the transparent substrate comprises molding a material on the transparent substrate, for example by injection molding a material such as LCP or transfer molding a material such as an opaque epoxy.

24. The method as claimed in claim 22, wherein the one or more opaque features formed on the transparent substrate define one or more recesses, each recess being configured to accommodate a corresponding optical emitter device or a corresponding optical detector device.

25. An optical system as claimed in claim 1, wherein at least one of:
each optical emitter device is configured to emit visible and/or infra-red light;
each optical emitter device comprises a surface emitting optical emitter device such as a surface emitting LED device or a surface emitting laser device such as a VCSEL device;
each optical emitter device comprises a plurality of optical emitters;
each optical emitter device comprises a 1D or 2D array of optical emitters;
each optical emitter device comprises a uniform array of optical emitters;
each optical detector device is configured to detect visible and/or infra-red light;
each optical detector device comprises a plurality of optical detectors;
each optical detector device comprises a plurality of light sensitive areas or pixels;
each optical detector device comprises a 1D or 2D array of optical detectors;
each optical detector device comprises a uniform array of optical detectors;
each optical detector device comprises an image sensor.
